(19) United States
(12) Patent Application Publication
(10) Pub. No.: US 2006/0214711 A1
(43) Pub. Date: Sep. 28, 2006

(54) Programmable pattern generator for digital power supply controller

(76) Inventors: Preston Forest Fick, Austin, TX (US); Donald E. Alfano, Round Rock, TX (US); Ka Y. Leung, Austin, TX (US)

Correspondence Address: HOWISON & ARNOTT, L.L.P, P.O. BOX 741715, DALLAS, TX, 75374-1715, US

(21) Appl. No.: 11/089,349

(22) Filed: Mar. 24, 2005

(51) Int. Cl. H03K 3/017

(52) U.S. Cl. 327/175

(57) ABSTRACT

A method is disclosed for programming a pattern generator wherein a provided graphical user interface enables the manipulation of a plurality of outputs of a digital pulse width modulator. Received user input is used to manipulate the graphical representation of at least one of the plurality of outputs of the digital pulse width modulator and source code is generated from this graphical representation. The source code may then be output to a controller of the digital pulse width modulator.

### CROSS-REFERENCE TO RELATED APPLICATIONS

This application is related to U.S. patent application Ser. No. 10/742,509, filed Dec. 19, 2003 (Atty. Dkt. No. CYGL-26,532) and entitled “Digital Control Circuit for Switching Power Supply With Pattern Generator,” which is incorporated herein by reference in its entirety.

### TECHNICAL FIELD OF THE INVENTION

The present invention relates to digital pulse width modulators for use with a digitally controlled power supply, and more particularly, to a system and method for programming output patterns for a digital pulse width modulator.

### BACKGROUND OF THE INVENTION

The digital pulse width modulator (DPWM) is capable of generating a plurality of phased outputs from a provided input. The manner of output provided by the DPWM is controlled by values provided to the DPWM from a control register. These values in the control register must be created and entered into the control register to provide the desired output. Presently there exists no easy manner for determining the particular register values needed to provide desired outputs from a DPWM. Thus, time intensive trial and error methods may be necessary if a pre-existing working solution is not available. Thus, there is a need for some manner for easily and efficiently programming the output of a DPWM in a manner that is beneficial to designers implementing these devices in various digital circuitries.

### SUMMARY OF THE INVENTION

The present invention disclosed and claimed herein, in one aspect thereof, comprises an apparatus and method for a programmable pattern generator. A graphical user interface is provided that enables the manipulation of a plurality of outputs of a digital pulse width modulator. User inputs are received to manipulate a graphical representation of at least one of the plurality of outputs of the digital pulse width modulator on the graphical user interface. Source code is generated from the provided graphical representation, and output to a controller of the digital pulse width modulator.

### BRIEF DESCRIPTION OF THE DRAWINGS

For a more complete understanding of the present invention and the advantages thereof, reference is now made to the following description taken in conjunction with the accompanying Drawings in which:

FIG. 1 is a schematic diagram of a switched power supply with a digital feedback loop;

FIG. 2 is a block diagram of a digital pulse width modulator with associated controller;

FIG. 3 is a functional block diagram of the programmable pattern generator for providing register values for the digital pulse width modulator;

FIG. 4a is an illustration of a graphical user interface provided by the programmable pattern generator;

FIG. 4b is an illustration of the source code generated by the programmable pattern generator;

FIG. 4c is and illustration of the waveform and register values created by the source code of FIG. 4b;

FIGS. 5a-5e illustrate a number of ways in which an output waveform may be manipulated through the graphical user interface of FIG. 4a;

FIG. 6 illustrates an additional graphical user interface provided by the programmable pattern generator;

FIG. 7 is a flow diagram illustrating a manner for generating register values using the programmable pattern generator; and

FIG. 8 is a flow diagram illustrating an alternative method for creating register values for the programmable pattern generator.

### DETAILED DESCRIPTION OF THE INVENTION

Referring now to the drawings, and more particularly to FIG. 1, there is illustrated a schematic diagram of a switched power supply including a digital control loop. The buck converter configuration illustrated in FIG. 1 includes a first transistor 102 having its source/drain path connected between V_{IN} and node 104. The gate of transistor 102 is connected to the positive output of a driver 106. The negative output of driver 106 is connected to the gate of transistor 108. The source/drain path of transistor 108 is connected between node 104 and V_{OUT} node 112. A capacitor 114 is located between node 112 and ground, and a load resistor 116 is located between node 112 and ground. The digital control loop 118 consist of an A/D converter 120, a PID 122, a filter 124 and digital pulse width modulator 126. Each of these are digitally controlled by a controller 128. The input end of the digital control loop 118 is connected to the V_{OUT} node 112. The output end of the digital control loop 118 is connected to the input of driver 106.

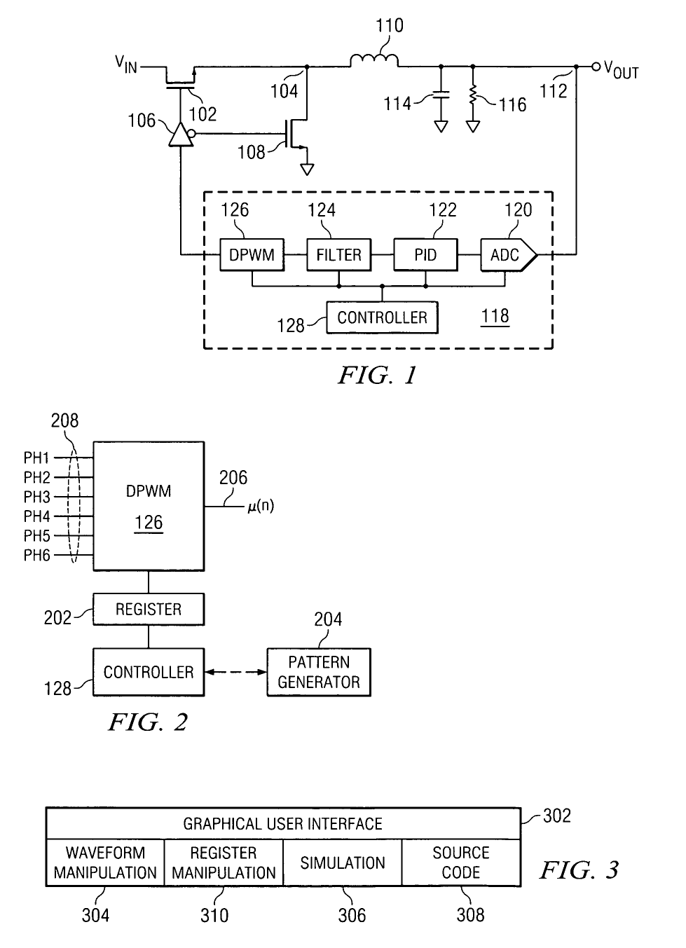

Referring now to FIG. 2, there is more fully illustrated the DPWM 126 and the controller 128. The DPWM 126 and controller 128 have a control register 202 located between them. The controller 128 places specified control values to control the output of the DPWM within the register 202. These control values control the operation of the DPWM 126 responsive to the input u(n) 206 applied thereto. In response to the input u(n) provided at input port 206 and the control values within register 202, the DPWM 126 is able to generate a plurality of output waveforms on output lines 208 labeled PH1 through PH6. The output waveforms provided from outputs 208 are programmable within the DPWM 126 in response to the control values within the register 202. Using the programmable pattern generator 204 of the present invention, the control values within the register 202 are created and stored within the control register 202 as described herein below.

Referring now to FIG. 3, there is illustrated a functional block diagram of the pattern generator 204 of the present disclosure. The pattern generator 204 includes a graphical user interface 302 enabling a user to physically interact with the control functionalities of the pattern generator 204. By accessing the graphical user interface 302, a user may use the waveform manipulation functionality 304 to physically shape the output waveforms of each of the six outputs from the DPWM. The user may physically create the waveform outputs using “drag and drop” and “point and click” techniques. After the waveforms have been created the user may perform simulations on the created waveforms to see if the desired output waveforms are operable using the simulation functionality 306. Simulation functionality 306 provides a simulation of output waveforms based upon generated waveform models created using the waveform manipulation functionality 304 for an input u(n) and provides results to the user of the operability of their designed waveforms. The results are provided to the user visually through the graphical user interface 302. If simulation results are satisfactory as generated by the simulation functionality 306, the physical waveform representations generated using the waveform manipulation functionality 304 are used to generate source code for operating a DPWM 126 in the designed manner using the source code functionality 308. In response to the data provided from the waveform manipulation functionality 304, the source code functionality 308 generates the source code values necessary to place the appropriate control register values within the control register 202 of the DPWM 126.

Rather than physically manipulating a visual representation of the output waveforms of the DPWM 126 using the waveform manipulation functionality 304, a user may input specific control register values using the register manipulation functionality 310. In this embodiment, control values are entered through the graphical user interface 302 that would be used within the control register 202 of the DPWM 126. These control values are used to generate a simulation using the simulation functionality module 306 responsive to a varied input u(n). The simulation helps the user to determine if the output waveforms operate in a desired fashion. The simulation functionality 306 provides a visual display of the simulation via the graphical user interface 302 so that a user may determine whether the provided register values are functioning in a desired manner. If so, these values are used to generate the appropriate source code using the source code functionality 308 in a manner similar to that described above. The source code creates the desired control values in the control register 202 of the DPVVM 126.

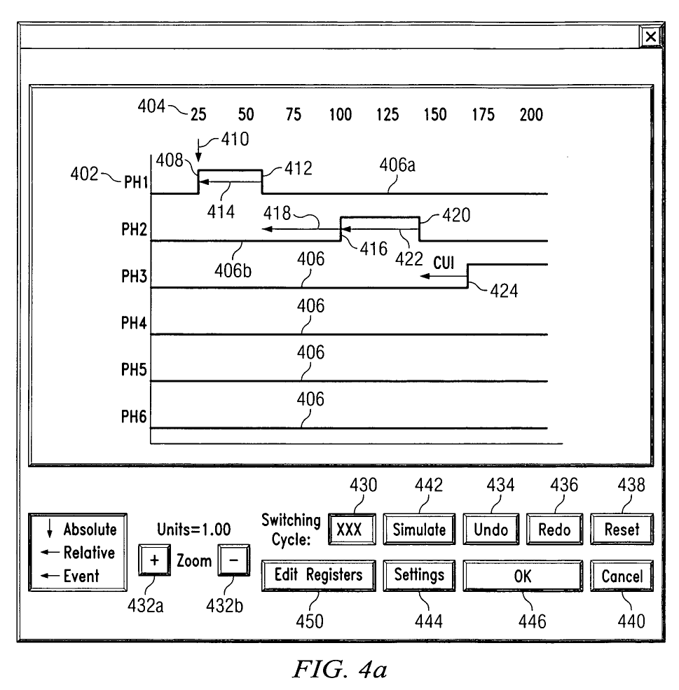

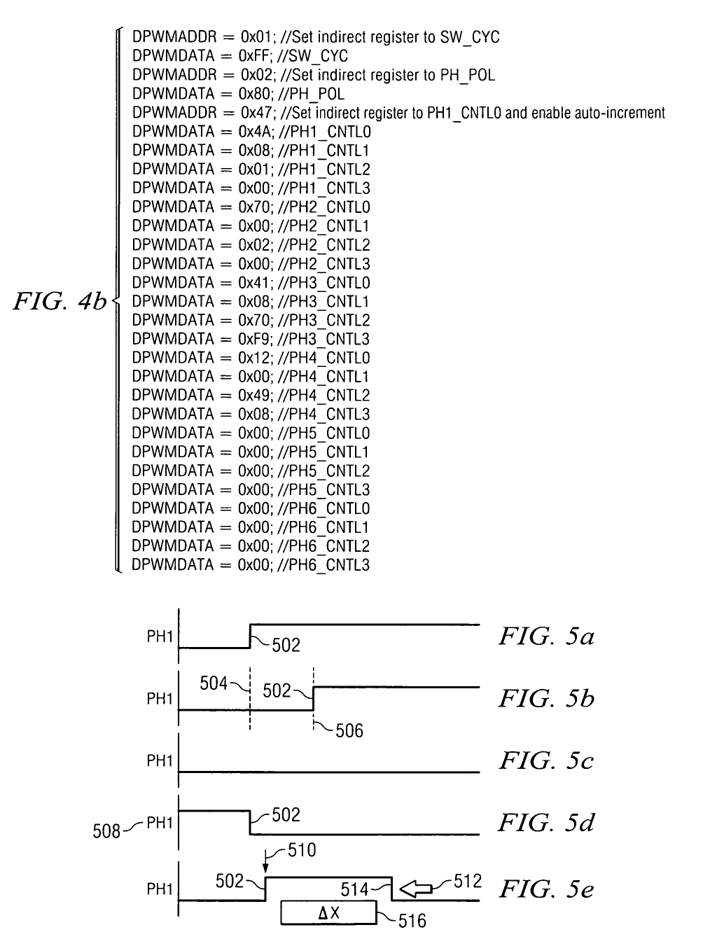

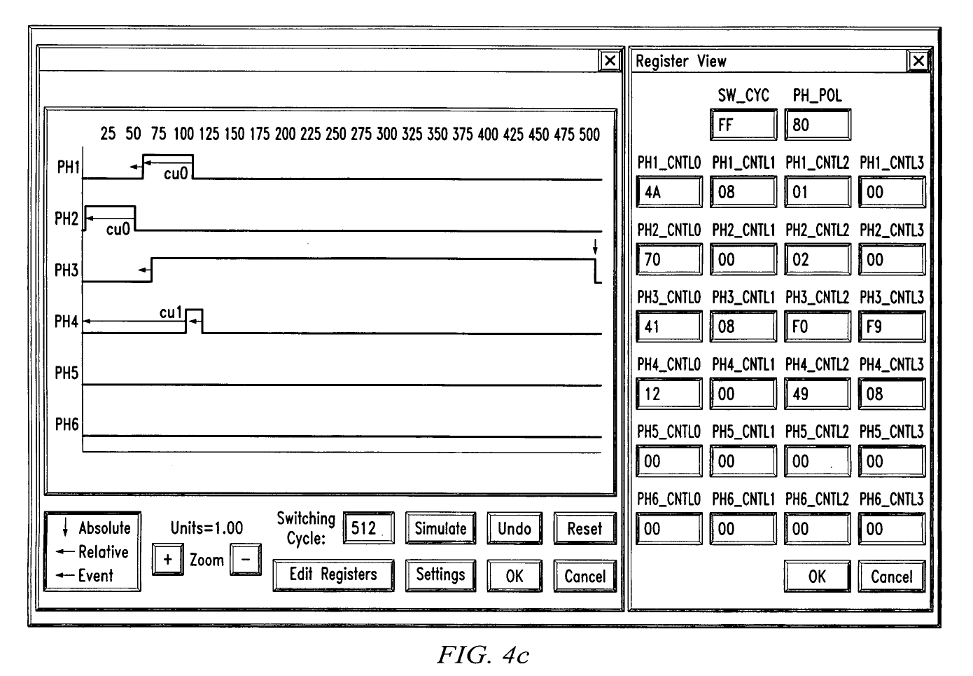

Referring now to FIG. 4a, there is provided an illustration of the graphical user interface 302 through which a user may visually manipulate the output waveforms to a desired configuration. The vertical axis of the screen includes each of the phase outputs 402 for the DPWM. Each phase output is identified by an indicator PH1-PH6, depending upon the phase output port the waveform is associated with. The horizontal axis indicates the scale 404 to be used with respect to the indicated waveforms. In the present illustration, the scale 404 is divided into 25 increment segments. As will be discussed more fully herein below, the scale 404 used in the horizontal axis may be adjusted as desired by the user.

Each of the phase outputs 402 has a waveform 406 associated therewith. The waveform 406a for phase one (PH1) includes a pulse beginning at scale marker 25. The graphical user interface of FIG. 4 enables a user to visually manipulate the output waveforms 406 associated with each of the phase outputs 402 and then simulate results from the waveforms. The manipulations of the output waveform 406 may be done in a number of fashions. One manipulation involves adding an edge to an output waveform 406. Referring now to the output waveform 406a of phase output one, an edge has been placed at 408. In this case, the edge 408 is a rising clock pulse and is an absolute edge as indicated by the arrow 410 associated with the edge 408. A user creates an absolute edge by indicating a point exactly at which the user desires an edge to appear.

Additional type of edges which may be created upon the output waveforms 406 include a relative edge and a functional edge. The relative edge is illustrated in waveform 406a as the falling pulse edge 412 of the output waveform 406a. A relative edge occurs a specific time or distance from another edge. In this case, the falling edge 410 is a relative edge with respect to the absolute edge 408. The arrow 414 indicates the edge with which the relative edge 410 has its relative relationship. Additional relative edges are illustrated in output waveform 406b associated with phase output two (PH2), wherein the rising clock edge 416 of output waveform 406 is a relative edge with respect to the falling edge 412 of waveform 406a. Edge 416 is a relative edge with respect to edge 412 as indicated by the arrow 418. Furthermore, falling edge 420 is a relative edge with respect to edge 416 of the output waveform 406b as indicated by arrow 422. The arrows indicating the absolute and relative edges may also be color coded in different colors to make them more apparent on the graphical user interface.

A functional edge is illustrated in the output waveform 406c of phase output 3 (PH3). Edge 424 has a functional relationship with respect to the input signal u(n) and an indicated point or edge. Thus, the edge 424 will be determined during the simulation mode described herein below with respect to the function that is associated with the selected functional edge. In the present example, the functional edge 424 has a constant time C associated therewith such that the relative functional edge 424 is a predetermined distance from the edge with which it is associated. However, it should be realized that any function, not just a constant, may be associated with a particular functional edge 424 and that multiple functional edge formulas may be utilized with respect to output waveforms 406. Also different functional edge formulas may be used within a single simulation.

To add an edge to the graphical user interface, the mouse is moved inside of the desired phase 402 at a desired time on scale 404. Guide numbers will appear inside the phase that the mouse is currently over. By double clicking the left mouse button a menu box will appear displaying the types of edges discussed herein above, namely the absolute edge, relative edge and functional edge. Absolute edges are added at the indicated point immediately after the type has been chosen. If a relative edge or a functional edge is selected, they are added once a left click on the edge that the added edge is related to. A message box will display when an event is added at a time not equal to its constant time. Clicking “yes” on the message box will simply add the edge using the constant time. The remainder of the waveforms 406 with respect to phases 4-6 are shown as flat lines which have not been physically manipulated by a user.

Referring now also to FIGS. 5a-5e, there are illustrated various manners in which an edge may be manipulated. In FIG. 5a, there is illustrated an edge 502 that has been previously established within a particular waveform 406. As illustrated in FIG. 5b, the edge 502 may be moved from its present position at 504 to a new position at 506. To move an absolute or relative edge to another position, the user left clicks and holds a pointer on the edge using a mouse while moving the edge to the newly desired position. Since the functional edges have a functional value they cannot be moved in this manner. These edges will be moved during a simulation.

Referring now to FIG. 5c, there is illustrated that the waveform associated with phase one has had the edge 502 deleted therefrom. To delete an edge, the user places the pointer on the edge using a mouse and right clicks on the edge to be deleted. When a menu pops up, a user selects the delete edge functionality. Deleting an edge that other edges are dependent upon will cause any dependent edges to be deleted as well.

Referring now to FIG. 5d, there is illustrated the manner in which the polarity of the phase one waveform may be altered. In FIG. 5d, edge 502 remains in the same position but has the polarity associated with the phase change. Thus, edge 502 is a falling edge in FIG. 5d going from a high clock level to a low clock level, whereas in FIG. 5a, the edge 502 is a rising clock pulse going from a low clock level to a high clock level. To change the polarity of a phase, the user left clicks on the phase one label 508 (PH1) to the left of the particular phase output waveform.

Referring now to FIG. 5e, wherein there is illustrated how a distance between two edges may be determined. In this case, a distance between edge 502 and edge 514 is determined. To determine the distance between two edges, a user left clicks on the first edge 502 one time by placing the pointer on the edge using the mouse, causing a marker 510 to appear on this edge. The user then left clicks on the second edge 514 using the pointer 512, and a message window 516 will appear illustrating the delta value between the first edge 502 and the second edge 514.

Referring now back to FIG. 4a, a length of the switching cycle may be changed by entering a new value within a switching cycle edit box 430. To change the length of the switching cycle, a user enters the newly desired switching cycle time into the switching cycle edit box 430. Additional functionality buttons on the graphical user interface includes zoom buttons 432. The plus zoom button 432a increases the magnification of the view of the waveforms 406 in 1×, 2× and 4× increments while the negative zoom button 432b decreases the magnification of the image in 1×, 2×and 4× increments. The undo button 434 removes a most previously occurring user action with respect to an output waveform 406. Thus, if a particular edge had just been added to a waveform 406, this edge would be removed. The redo button 436 enables a user to recreate an action which was just previously undone by the undo button 545. Thus, as in the previous example, if the added edge had been deleted by the undo button 434, the edge may be placed back within the waveform 406 using the redo button 436. The reset button 438 resets the waveforms 406 to previously establish default values. The cancel button 440 cancels execution of any process that has been started by the application such as a simulation or generation of source code.

The simulations button 442 enables a simulation of the change of the input u(n) and the shrinking and growing of the functional edges based upon the change of u(n). The arrow up and down buttons may be used to increase and decrease the value of u(n). This will cause the functional values to shrink/grow and all of the edges in the graphical user interface will move accordingly. By varying the input value u(n), a user may determine whether the programmed output waveforms for the six phases will operate appropriately or would cause the DPWM 126 to malfunction. The settings button 444 enable a number of settings with respect to the graphical user interface to be altered. These include the edge attributes (arrows and labels); scale and vector lines on the edges, which may be turned on or off; and adjusting the spacing for the scale. By pressing the OK button 446, a user begins creation of the source code required in order to create the control values necessary for generating the waveform displays created within the graphical user interface. This created source code may then be downloaded into the control registers 202 of the DPWM 126. An example of created source code is illustrated in FIG. 4b, and the waveform image and register values created by or used to create the source code are illustrated in FIG. 4c.

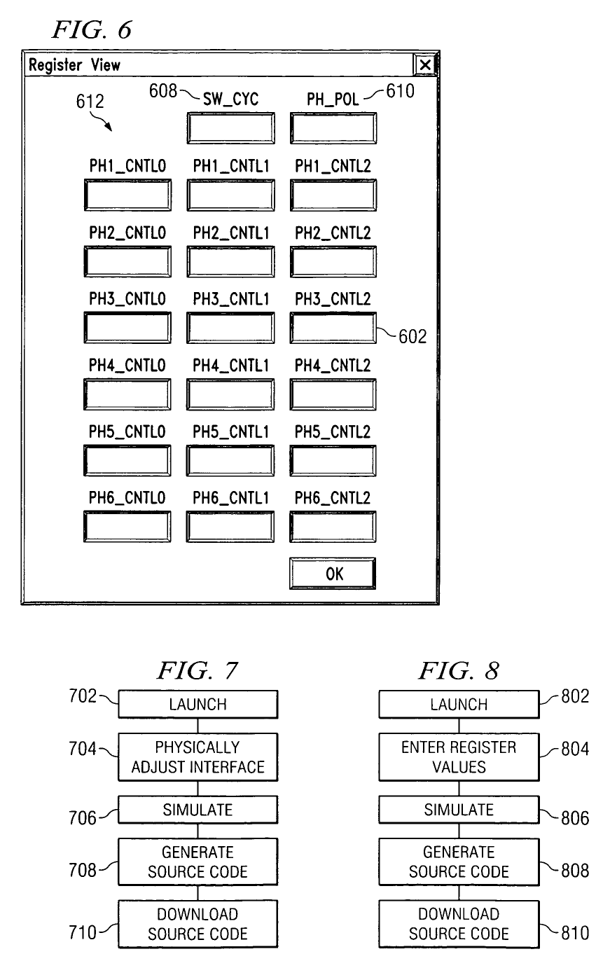

In addition to creating the source code by physically generating the desired output waveforms on the graphical user interface, a user may create the source code by entering predetermined register values into a graphical user interface of a table of values of the control register similar to the one illustrated in FIG. 4c. A graphical user interface providing a manner for entering these register values is accessed by actuating the edit registers button 450. When the edit registers button 450 is actuated, a graphical user interface appearing similar to that as illustrated in FIG. 6 is presented to the user. As can be seen, this graphical user interface provides a number of entry fields for entering data associated with various register control values including the switching cycle 608, phase polarity 610 and control values 612 for each of the six phases of the output waveform. A user may go through and individually enter values into the data field 602 associated with each of the register values. Once these register values have been entered into the register table, a simulation of the waveforms provided by the entered registered values may be accomplished by actuating the simulate button 442. As before, the value of u(n) may be increased or decreased using the up and down keys of an associated keyboard in order to determine whether the output waveforms associated with the six phases will operate in a desired manner responsive to the provided register values. A visual representation of the waveforms would also be provided in the graphical user interface of FIG. 4. If it is determined that the entered register values operate in an appropriate manner, source code may be created by pressing the OK button 446. The generated source code may then be downloaded into the control register 202 for the DPWM 126 to provide the tested register values.

Referring now to FIG. 7, there is a flow diagram illustrating the manner for creating control values for a DPWM control register by physically manipulating the interface described with respect to FIG. 4, the application is launched at step 702 and a user physically adjusts the graphical user interface at 704 using the techniques described previously with respect to FIGS. 4 and 5. Once the desired output waveforms are visually created at step 704 using the graphical interface, a user may simulate the results for the established waveforms at step 706 to determine if the output waveforms are operating in a desired manner. Once the desired waveforms have been created and simulated, the source code associated with the created waveforms is created at step 708. Once the source code has been created the source code may be downloaded at any desired time into a controller or to the registers of the DPWM in order to have the output waveforms of the DPWM operate in the desired manner.

Referring now to FIG. 8, there is illustrated an alternative method of operation of the system, wherein the data entry method is via the register values as described with respect to FIG. 6. In this case, the application is launched at step 802, and a user enters the desired register values that they have created or previously obtained at step 804. A simulation is performed at step 806 using these provided register values to determine if the output waveforms are operating in a desired fashion. Once the register values have been checked, the source code associated with these register values may be generated from the entered values at step 808. The generated source code may then be downloaded at step 810 to the desired controller or control register associated with a DPWM.

Although the preferred embodiment has been described in detail, it should be understood that various changes, substitutions and alterations can be made therein without departing from the scope of the invention as defined by the appended claims.

What is claimed is:

1. A method, comprising the steps of:
providing a graphical user interface enabling manipulation of a plurality of outputs for a digital pulse width modulator;
receiving user input to manipulate a graphical representation of at least one of the plurality of outputs for the pulse width modulator on the graphical user interface;
generating source code from the graphical representation; and
outputting the source code to a controller for the pulse width modulator.

2. The method of claim 1, further comprising the step of displaying the graphical representation on the graphical user interface.

3. The method of claim 1, further comprising the step of configuring the graphical representation to display a pulse edge at a predetermined location responsive to the user input.

4. The method of claim 1, further comprising the step of configuring the graphical representation to display a pulse edge at a first location relative to a second pulse edge at a second location responsive to the user input.

5. The method of claim 1, further comprising the step of configuring the graphical representation to display a pulse edge at a first location responsive to the user input and a predetermined function.

6. The method of claim 5, further including the step of generating the pulse edge based upon a provided input to the predetermined function.

7. The method of claim 1, further including the step of configuring the graphical representation to move a pulse edge from a first position to a second position responsive to a user input.

8. The method of claim 1, further including the step of simulating an output waveform for at least one of the plurality of outputs responsive to the graphical representation of the at least one of the plurality of outputs.

9. An apparatus, comprising:
a computer-readable storage medium containing a set of instructions for a general purpose computer;
wherein execution of the set of instructions by the general purpose computer enables the general purpose computer to:
provide a graphical user interface enabling manipulation of a plurality of outputs of a digital pulse width modulator;
receive user input to manipulate a graphical representation of at least one of the plurality of outputs of the digital pulse width modulator on the graphical user interface;
generate source code from the graphical representation; and
output the source code to a controller of the digital pulse width modulator.

10. The apparatus of claim 9, wherein the execution of the set of instructions by the general purpose computer further enables the general purpose computer to display the graphical representation on the graphical user interface.

11. The apparatus of claim 9, wherein the execution of the set of instructions by the general purpose computer further enables the general purpose computer to configure the graphical representation to display a pulse edge at a predetermined location responsive to the user input.

12. The apparatus of claim 9, wherein the execution of the set of instructions by the general purpose computer further enables the general purpose computer to configure the graphical representation to display a pulse edge at a first location relative to a second pulse edge at a second location responsive to the user input.

13. The apparatus of claim 9, wherein the execution of the set of instructions by the general purpose computer further enables the general purpose computer to configure the graphical representation to display a pulse edge at a first location responsive to the user input and a predetermined function.

14. The apparatus of claim 9, wherein the execution of the set of instructions by the general purpose computer further enables the general purpose computer to generate the pulse edge based upon a provided input to the predetermined function.

15. The apparatus of claim 9, wherein the execution of the set of instructions by the general purpose computer further enables the general purpose computer to configure the graphical representation to move a pulse edge from a first position to a second position responsive to a user input.

16. The apparatus of claim 9, wherein the execution of the set of instructions by the general purpose computer further enables the general purpose computer to simulate an output waveform for at least one of the plurality of outputs responsive to the graphical representation of the at least one of the plurality of outputs.

17. As apparatus for programing an output of a digital pulse width modulator, comprising:
a graphical user interface enabling a user to provide inputs for programing the output of the digital pulse width modulator and providing a representation of a plurality of waveforms;
a waveform manipulation module for altering the representation of at least one of the plurality of waveforms responsive to a user input; and
a source code function for generating source code responsive to the representation of the at least one of the plurality of waveforms.

18. The apparatus of claim 17, further including a register module enabling a user to enter predetermined control register values through the graphical user interface for creating the output of the digital pulse width modulator.

19. The apparatus of claim 18, wherein the source code function further generates the source code responsive to the predetermined control register values.

20. The apparatus of claim 17, further including:
a simulation function for simulating an output of the digital pulse width modulator responsive to an input and the representation of the at least one of the plurality of waveforms.
